(19) United States
(12) Patent Application Publication
(10) Pub. No.: US 2015/0017477 A1
(43) Pub. Date: Jan. 15, 2015

(54) PRINTED CIRCUIT BOARD AND MANUFACTURING METHOD THEREOF

(71) Applicant: SAMSUNG ELECTRO-MECHANICS CO., LTD., Suwon (KR)

(72) Inventors: Cheol Ho HEO, Busan (KR); Kwang Jin Kim, Busan (KR); Jin Su Yeo, Busan (KR); Young Ho Lee, Busan (KR); Chul Min Lee, Changwon (KR); Joong Hyuk Jung, Busan (KR)

(73) Assignee: SAMSUNG ELECTRO-MECHANICS CO., LTD., Suwon (KR)

(21) Appl. No.: 14/325,658

(22) Filed: Jul. 8, 2014

(30) Foreign Application Priority Data
Jul. 9, 2013 (KR) 10-2013-0080404

(51) Int. Cl. B23K 1/00; H05K 3/40; H05K 1/09

(52) U.S. Cl. CPC B23K 1/0016; H05K 1/09; H05K 3/40; H05K 2201/0338; B23K 2001/12; H05K 2203/043
USPC 428/686; 228/203

(57) ABSTRACT

The present invention relates to a printed circuit board, which includes a metal circuit layer electrically connected to an electronic component, a solder layer formed on an upper surface of the metal circuit layer, an intermetallic compound layer formed between the solder layer and the metal circuit layer, and a chunk portion formed in the intermetallic compound layer according to the thickness of the metal circuit layer, wherein the thickness of the metal circuit layer is 20 to 50 μm, and a manufacturing method thereof.

### CROSS-REFERENCE TO RELATED APPLICATIONS

Claim and incorporate by reference domestic priority application and foreign priority application as follows:

### CROSS REFERENCE TO RELATED APPLICATION

This application claims the benefit under 35 U.S.C. Section 119 of Korean Patent Application Serial No. 10-2013-0080404, entitled filed Jul. 9, 2013, which is hereby incorporated by reference in its entirety into this application.

### BACKGROUND OF THE INVENTION

1. Field of the Invention

The present invention relates to a printed circuit board and a manufacturing method thereof, and more particularly, to a printed circuit board and a manufacturing method thereof that can improve reliability between an electronic component mounted on a printed circuit board and circuit wiring.

2. Description of the Related Art

In recent times, there are increasing demands for miniaturization for portability as well as various functions of electronic products. Due to this trend, various electronic components are mounted on substrates of the electronic products, and there is an increasing possibility that the electronic products are dropped or impacted when the electronic products are carried. Accordingly, high reliability of the electronic products is required. Particularly, in order to prevent a failure that the electronic component is separated from the substrate, high reliability is required for the solder interface that connects the electronic component and the substrate.

Typically, there are two methods of connecting various electronic components such as a die and a main board: a wire bonding method and a solder joint method. Among them, when using the solder joint method, reliability on the solder interface is a very important factor.

Meanwhile, according to high density of the electronic components, PCB surface treatment technologies become diverse. According to the demand of the times for PCB products that become thinner and dense, in recent times, the PCB surface treatment is changed from electro Ni/Au surface treatment to electroless surface treatment that can easily implement tailless in order to overcome the problems such as process simplification and noise free.

Particularly, when the surface treatment method is an electroless nickel (Ni)-gold (Au) (hereinafter, ENIG) plating layer or an electroless nickel (Ni)-palladium (Pd)-gold (Au) (hereinafter, ENEPIG) plating layer including Ni, destruction by impact occurs in solder and the ENIG and ENEPIG plating layers which are nickel plating layers. In this electroless surface treatment, an intermetallic compound (IMC) layer by diffusion of Ni and P atoms is formed between solder and a metal circuit layer when mounting an electronic component and performing solder joint for wire bonding after performing surface treatment on the metal circuit layer.

In this intermetallic compound, a needle structure or a chunk structure is formed according to the temperature of a reflow process for solder joint. At this time, in the intermetallic compound, the chunk structure which is conglomerated is formed to improve reliability when the temperature of the reflow process is high, and the needle structure in which a plurality of needles are erect is formed when the temperature of the reflow process is low.

However, there are difficulties in the practical application due to the limitations in the temperature of the reflow process according to the electronic components.

### Related Art Document

### Patent Document

Patent Document 1: Korean Patent Laid-Open Publication No. 2010-0102033

### SUMMARY OF THE INVENTION

The present invention has been invented in order to overcome the above-described problems and it is, therefore, an object of the present invention to provide a printed circuit board and a manufacturing method thereof that can improve reliability by controlling the shape of an intermetallic compound in a method of connecting a surface-treated metal circuit layer and an electronic component using solder joint.

In accordance with one aspect of the present invention to achieve the object, there is provided a printed circuit board including: a metal circuit layer electrically connected to an electronic component; a solder layer formed on an upper surface of the metal circuit layer; an intermetallic compound layer formed between the solder layer and the metal circuit layer; and a chunk portion formed in the intermetallic compound layer according to the thickness of the metal circuit layer, wherein it is preferred that the thickness of the metal circuit layer is 20 to 50 μm.

It is preferred that the thickness of the metal circuit layer is 20 to 25 μm when the width of the metal circuit layer is 20 to 30 μm.

It is preferred that the thickness of the metal circuit layer is 25 to 30 μm when the width of the metal circuit layer is 30 to 40 μm.

It is preferred that the thickness of the metal circuit layer is 30 to 40 μm when the width of the metal circuit layer is 40 to 50 μm.

It is preferred that the thickness of the metal circuit layer is 40 to 50 μm when the width of the metal circuit layer is 50 to 70 μm.

It is preferred that the thickness of the intermetallic compound layer is 0.1 to 1.5 μm.

In accordance with another aspect of the present invention to achieve the object, there is provided a method of manufacturing a printed circuit board including: forming a metal circuit layer on a base substrate; surface-treating the metal circuit layer; and forming an intermetallic compound layer including a chunk portion from the metal circuit layer, wherein in forming the intermetallic compound layer, the ratio of the chunk portion is controlled according to the thickness of the metal circuit layer.

In forming the intermetallic compound layer, it is preferred that the thickness of the metal circuit layer is 20 to 50 μm.

In forming the intermetallic compound layer, reflow soldering may be performed at a temperature of 240 to 260° C.

It is preferred that the thickness of the metal circuit layer is 20 to 25 μm when the width of the metal circuit layer is 20 to 30 μm.

It is preferred that the thickness of the metal circuit layer is 25 to 30 μm when the width of the metal circuit layer is 30 to 40 μm.

It is preferred that the thickness of the metal circuit layer is 30 to 40 μm when the width of the metal circuit layer is 40 to 50 μm.

It is preferred that the thickness of the metal circuit layer is 40 to 50 μm when the width of the metal circuit layer is 50 to 70 μm.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of a printed circuit board in accordance with an embodiment of the present invention;

FIG. 2 is a photograph of a cross-section of the printed circuit board in accordance with an embodiment of the present invention; and

FIG. 3 is a flowchart showing a process of manufacturing a printed circuit board in accordance with an embodiment of the present invention.

### DETAILED DESCRIPTION OF THE PREFERABLE EMBODIMENTS

Hereinafter, specific embodiments of the present invention will be described with reference to the drawings. The following embodiments merely illustrate the present invention, and the present invention is not limited to the following embodiments.

In describing the present invention, specific descriptions of well-known techniques are omitted so as not to unnecessarily obscure the embodiments of the present invention. The following terms are defined in consideration of functions of the present invention and may be changed according to users or operator's intentions or customs. Thus, the terms shall be defined based on the contents described throughout the specification.

The technical sprit of the present invention should be defined by the attached claims, and the following embodiments are provided as examples to efficiently convey the technical spirit of the invention to those skilled in the art.

Hereinafter, the present invention will be described in detail with reference to the accompanying drawings.

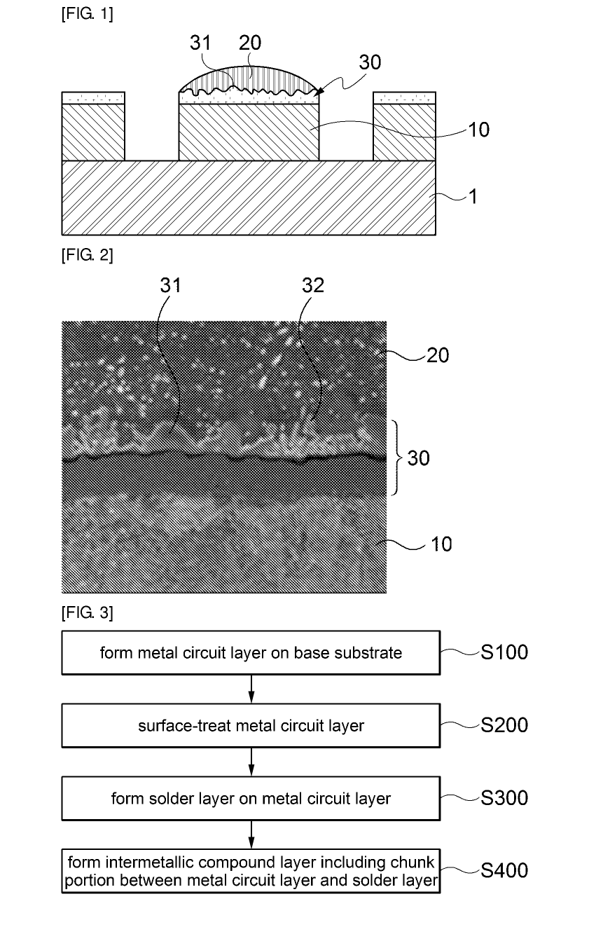

FIG. 1 is a cross-sectional view of a printed circuit board in accordance with an embodiment of the present invention, and FIG. 2 is a photograph of a cross-section of the printed circuit board in accordance with an embodiment of the present invention.

As shown in FIGS. 1 and 2, a printed circuit board in accordance with an embodiment of the present invention includes a metal circuit layer 10 electrically connected to an electronic component, a solder layer 20 formed on an upper surface of the metal circuit layer 10; an intermetallic compound layer 30 formed between the solder layer 20 and the metal circuit layer 10; and a chunk portion 31 formed in the intermetallic compound layer 30 according to the thickness of the metal circuit layer 10.

The metal circuit layer 10, which is electrically connected to the electronic component (not shown in the drawing), may be formed on a base substrate 1. Here, the metal circuit layer 10 may be made of copper (Cu) and formed by a plating process and a patterning process.

At this time, the metal circuit layer 10 may be formed to have a thickness of 20 to 50 μm to form the controllable intermetallic compound layer 30 after a reflow soldering process of forming the solder layer 20 thereon.

The intermetallic compound layer 30 may be formed from an electroless surface treatment plating layer (not shown in the drawing) formed by surface-treating the metal circuit layer 10 in the reflow process of bonding the solder layer 20 on the metal circuit layer 10 for mounting of the electronic component.

Here, the electroless surface treatment plating layer may be an electroless nickel immersion gold (ENIG) plating layer formed of an electroless nickel plating film and an electroless gold plating film or an electroless nickel electroless palladium immersion gold (ENEPIG) plating layer formed of an electroless nickel plating film, an electroless palladium plating film, and an electroless gold plating film.

That is, the electroless surface treatment plating layer is formed until the reflow soldering process, and during the reflow soldering process, the electroless gold plating film included in the electroless surface treatment plating layer is absorbed into the solder layer 20, and a main component Sn of the solder layer 20 and some copper (Cu) metal from the metal circuit layer 10 are absorbed into nickel and gold of the electroless surface treatment plating layer to form a new layer, that is, the intermetallic compound layer 30.

Here, even though the electroless surface treatment plating layer has a structure of the ENIG plating layer or the ENEPIG plating layer, it is preferred that the thickness of the nickel plating film of the electroless surface treatment plating layer is 3 to 10 μm and the thickness of the gold plating film is 0.1 to 1 μm. When the thickness of the nickel plating film is less than 3 μm, the metal circuit layer 10 under the nickel plating film may be exposed or the metal circuit layer 10 may be oxidized. When the thickness of the nickel plating film is greater than 10 μm, the intermetallic compound layer 30 may be broken.

Further, it is preferred that the thickness of the intermetallic compound layer 30 is 0.1 to 1.5 μm. When the thickness of the intermetallic compound layer 30 is less than 0.1 μm, wettability of solder may be deteriorated, and when the thickness of the intermetallic compound layer 30 is greater than 1.5 μm, nickel may be oxidized.

Meanwhile, the intermetallic compound layer 30, as shown in FIG. 2, may include the chunk portion 31 having a chunk structure in which the intermetallic compound is conglomerated and a needle portion 32 having a needle structure in which the intermetallic compound is formed in the shape of a plurality of erect needles.

Here, in the embodiment of the present invention, the chunk portion 31 may be formed by adjusting the thickness of the metal circuit layer 10.

Particularly, as the thickness of the metal circuit layer 10 increases, the area ratio of the chunk portion 31 in the intermetallic compound layer 30 increases than that of the needle portion 32. As the ratio of the chunk portion 31 increases, the adhesion between the solder layer 20 and the metal circuit layer 10 increases, thus improving reliability with the electronic component.

At this time, the reason why the ratio of the chunk portion 31 increases according to the increase in the thickness of the metal circuit layer 10 is that thermal conductivity decreases according to the increase in the thickness of the metal circuit layer 10 when heat is applied to the solder layer 20 during the reflow soldering process and thus the ratio of the chunk portion 31 increases than that of the needle portion 32.

The thickness of the metal circuit layer 10 increases according to the increase in the width of the metal circuit layer 10. The ratio of the chunk portion 31 to the entire area according to the width and thickness of the metal circuit layer 10 is as in Table 1.

TABLE 1

| Width of metal | Thickness of metal | Ratio of chunk portion in |
|---|---|---|
| circuit layer | circuit layer | intermetallic compound layer |
| 20~30 μm | Less than 15 μm | Within 30% |
| | 15~20 μm | 30~70% |
| | 20~25 μm | 70~100% |
| 30~40 μm | Less than 20 μm | Within 40% |
| | 20~25 μm | 40~70% |
| | 25~30 μm | 70~100% |
| 40~50 μm | Less than 20 μm | Within 10% |
| | 20~25 μm | 10~25% |
| | 25~30 μm | 25~60% |
| | 30~40 μm | 60~100% |
| 50~70 μm | Less than 20 μm | Within 10% |
| | 20~25 μm | 10~30% |
| | 25~30 μm | 30~60% |
| | 30~40 μm | 60~80% |
| | 40~50 μm | 80~100% |

Looking into the ratio of the chunk portion 31 according to the width of the metal circuit layer 10 and the thickness of the metal circuit layer 10 with reference to Table 1, when the width of the metal circuit layer 10 is 20 to 30 μm and the thickness thereof is 20 to 25 μm, the ratio of the chunk portion 31 to the entire area in the intermetallic compound layer 30 is the highest.

Further, when the width of the metal circuit layer 10 is 30 to 40 μm and the thickness thereof is 25 to 30 pm, the ratio of the chunk portion 31 to the entire area in the intermetallic compound layer 30 is the highest. When the width of the metal circuit layer 10 is 40 to 50 μm and the thickness thereof is 30 to 40 μm, the ratio of the chunk portion 31 in the intermetallic compound layer 30 is the highest. When the width of the metal circuit layer 10 is 50 to 70 μm and the thickness thereof is 40 to 50 μm, the ratio of the chunk portion 31 to the entire area in the intermetallic compound layer 30 is the highest.

Therefore, since the printed circuit board in accordance with an embodiment of the present invention can improve the adhesion between the solder layer and the metal circuit layer by controlling the thickness of the metal circuit layer to secure the ratio of the chunk portion to the entire area in the intermetallic compound layer, it is possible to improve the resistance to external impact and the reliability between the electronic component and the metal circuit layer.

FIG. 3 is a flowchart showing a process of manufacturing a printed circuit board in accordance with an embodiment of the present invention.

A process of manufacturing a printed circuit board in accordance with an embodiment of the present invention will be described below with reference to the drawing.

First, the step S100 of forming a metal circuit layer 10 on a base substrate 1 is performed.

Here, the metal circuit layer 10 is electrically connected to an electronic component when the electronic component is mounted. The metal circuit layer 10 may be formed by forming a metal layer on the base substrate 1 through a typical plating process and performing exposure, developing, and etching processes using photoresist on the metal layer formed through the plating process.

At this time, the thickness of the metal circuit layer 10 may be determined according to the width of the metal circuit layer 10.

Next, the step S200 of surface-treating the metal circuit layer 10 is performed.

Here, an electroless surface treatment plating layer (not shown in the drawing) is formed on the metal circuit layer 10 by ENIG or ENEPIG which is an electroless surface treatment.

At this time, it is preferred that the thickness of a nickel plating film of the electroless surface treatment plating layer is 3 to 10 μm and the thickness of a gold plating film is 0.1 to 1 μm. When the thickness of the nickel plating film is less than 3 μm, the metal circuit layer 10 under the nickel plating film may be exposed or the metal circuit layer 10 may be oxidized. When the thickness of the nickel plating film is greater than 10 μm, an intermetallic compound layer 30 may be broken.

Next, the step S300 of forming a solder layer 20 on the electroless surface treatment plating layer is performed.

After that, the step S400 of forming the intermetallic compound layer 30 including a chunk portion 31 from the metal circuit layer 10 is performed.

Here, a reflow soldering process for mounting the electronic component is performed. The electroless surface treatment plating layer is formed until the reflow soldering process, and during the reflow soldering process, the electroless gold plating film included in the electroless surface treatment plating layer is absorbed into the solder layer 20, and a main component Sn of the solder layer 20 and some copper (Cu) metal from the metal circuit layer 10 are absorbed into nickel and gold of the electroless surface treatment plating layer to form a new layer, that is, the intermetallic compound layer 30. When the thickness of the intermetallic compound layer 30 formed from the metal circuit layer 10 is less than 0.1 μm, wettability of solder may be deteriorated, and when the thickness of the intermetallic compound layer 30 is greater than 1.5 μm, nickel may be oxidized. Thus, the intermetallic compound layer 30 may be formed to have a thickness of 0.1 to 1.5 μm and the thickness of the chunk portion 31 described below may be limited.

Here, the chunk portion 31 is formed in the intermetallic compound layer 30 in the shape in which the intermetallic compound is conglomerated. The intermetallic compound layer 30 may include a needle portion 32 having a needle structure in which the intermetallic compound is formed in the shape of a plurality of erect needles as well as the chunk portion 31.

Meanwhile, it is preferred that the reflow soldering process is performed at a temperature of 240 to 260° C. to increase the ratio of the chunk portion 31 that can increase the adhesion between the solder layer 20 and the metal circuit layer 10.

Particularly, the ratio of the chunk portion 31 may be controlled according to the thickness of the metal circuit layer 10.

Here, the larger the thickness of the metal circuit layer 10, the lower the thermal conductivity. Thus, the ratio of the chunk portion 31 to the entire area in the intermetallic compound layer 30 increases. Since the adhesion between the solder layer 20 and the metal circuit layer 10 increases according to the increase in the ratio of the chunk portion 31, the reliability with the electronic component is improved.

That is, since it is possible to improve the adhesion between the solder layer having the electronic component mounted thereon and the metal circuit layer by increasing the thickness of the metal circuit layer 10 to secure the ratio of the chunk portion 31 in the intermetallic compound layer 30, it is possible to improve the resistance to external impact and the reliability between the electronic component and the metal circuit layer.

As described above, the printed circuit board and the manufacturing method thereof in accordance with an embodiment of the present invention can improve the resistance to external impact and the reliability between the electronic component and the metal circuit layer by controlling the thickness of the metal circuit layer to secure the ratio of the chunk portion in the intermetallic compound layer.

Although the present invention has been described in detail with reference to the preferable embodiments, it will be appreciated by those skilled in the art that various modifications may be made in these embodiments without departing from the scope of the present invention.

Therefore, the scope of the present invention should not be limited by the described embodiments but defined by the appended claims and their equivalents.

What is claimed is:

1. A printed circuit board comprising:
a metal circuit layer electrically connected to an electronic component;
a solder layer formed on an upper surface of the metal circuit layer;
an intermetallic compound layer formed between the solder layer and the metal circuit layer; and
a chunk portion formed in the intermetallic compound layer according to the thickness of the metal circuit layer, wherein the thickness of the metal circuit layer is 20 to 50 μm.

2. The printed circuit board according to claim 1, wherein the thickness of the metal circuit layer is 20 to 25 μm when the width of the metal circuit layer is 20 to 30 μm.

3. The printed circuit board according to claim 1, wherein the thickness of the metal circuit layer is 25 to 30 μm when the width of the metal circuit layer is 30 to 40 μm.

4. The printed circuit board according to claim 1, wherein the thickness of the metal circuit layer is 30 to 40 μm when the width of the metal circuit layer is 40 to 50 μm.

5. The printed circuit board according to claim 1, wherein the thickness of the metal circuit layer is 40 to 50 μm when the width of the metal circuit layer is 50 to 70 μm.

6. The printed circuit board according to claim 1, wherein the thickness of the intermetallic compound layer is 0.1 to 1.5 μm.

7. A method of manufacturing a printed circuit board, comprising:
forming a metal circuit layer on a base substrate;
surface-treating the metal circuit layer; and
forming an intermetallic compound layer comprising a chunk portion from the metal circuit layer, wherein in forming the intermetallic compound layer, the ratio of the chunk portion is controlled according to the thickness of the metal circuit layer.

8. The method of manufacturing a printed circuit board according to claim 7, wherein in forming the intermetallic compound layer, the thickness of the metal circuit layer is 20 to 50 μm.

9. The method of manufacturing a printed circuit board according to claim 7, wherein in forming the intermetallic compound layer, reflow soldering is performed at a temperature of 240 to 260° C.

10. The method of manufacturing a printed circuit board according to claim 7, wherein the thickness of the metal circuit layer is 20 to 25 μm when the width of the metal circuit layer is 20 to 30 μm.

11. The method of manufacturing a printed circuit board according to claim 7, wherein the thickness of the metal circuit layer is 25 to 30 μm when the width of the metal circuit layer is 30 to 40 μm.

12. The method of manufacturing a printed circuit board according to claim 7, wherein the thickness of the metal circuit layer is 30 to 40 μm when the width of the metal circuit layer is 40 to 50 μm.

13. The method of manufacturing a printed circuit board according to claim 7, wherein the thickness of the metal circuit layer is 40 to 50 μm when the width of the metal circuit layer is 50 to 70 μm.
